(19) United States
(12) Patent Application Publication
(10) Pub. No.: US 2003/0168666 A1
(43) Pub. Date: Sep. 11, 2003

(54) Semiconductor light emitting device, semiconductor laser device, and light emitting apparatus using the same

(76) Inventors: Hiroyuki Okuyama, Kanagawa (JP); Goshi Biwa, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/341,659

(22) Filed: Jan. 14, 2003

(30) Foreign Application Priority Data
Jan. 18, 2002 (JP) JP2002-010217

(51) Int. Cl. H01L 27/15

(52) U.S. Cl. 257/80

(57) ABSTRACT

A semiconductor light emitting device including an active layer formed on a tilt crystal is provided. The device generates induced emission light by optical pumping, and has an excellent luminous efficiency. The active layer has a multi-quantum well structure including, for example, an InGaN layer as a quantum well. The contents of In and Ga in the InGaN layer satisfy a relation of In/(In+Ga)≧0.9. The device is equivalent to a super luminescent diode, and if having a resonance structure, it becomes a laser diode. In particular, a pyramid type laser diode can be also realized.

### BACKGROUND OF THE INVENTION

The present invention relates to a new semiconductor light emitting device capable of emitting light by optical pumping or the like, and a light emitting apparatus using the same. The present invention also relates to a new semiconductor laser device having a pyramid shape, and a light emitting apparatus using the same.

GaN based compound semiconductors have become a focus of attention as semiconductor materials for semiconductor light emitting devices, and a variety of device designs and trials have been made to improve characteristics of semiconductor light emitting devices using GaN based compound semiconductors.

The GaN based semiconductor light emitting device emits light having a wavelength in a short-wavelength region, and therefore, it allows emission of light of blue or green. Accordingly, a full-color image display unit can be fabricated, for example, by combining the GaN based semiconductor light emitting devices with GaAs based semiconductor light emitting devices allowing emission of light of red.

The above-described GaN based semiconductor light emitting device can be fabricated by forming a mask having an opening on a sapphire substrate, forming a nitride layer by selective growth from the opening, and sequentially forming a cladding layer, a guide layer, and an active layer on a tilt growth plane of the nitride layer by selective growth. Such a light emitting device allows emission of light of green or blue.

### SUMMARY OF THE INVENTION

The present invention has been made to improve the above-described semiconductor light emitting device.

An object of the present invention is to provide a new semiconductor light emitting device capable of narrowing a half-value width of an emission wavelength peak and enhancing a luminous efficiency.

Another object of the present invention is to provide a semiconductor light emitting device capable of realizing light emission excellent in directivity.

A further object of the present invention is to provide a new light emitting apparatus allowing planar light emission.

Still a further object of the present invention is to provide a new semiconductor laser device having a so-called pyramid shape and a light emitting apparatus using the same.

To achieve the above objects, according to a first aspect of the present invention, there is provided a semiconductor light emitting device including a tilt crystal made from a compound semiconductor, the tilt crystal having outer planes, at least one of which is taken as a tilt plane, and an active layer formed on the tilt crystal, wherein the device generates induced emission light by pumping light absorbed in the active layer.

The semiconductor light emitting device according to this first aspect is a new light emitting device capable of emitting light by optical pumping. The device preferably includes an active layer having a multi-quantum well structure including an InGaN layer as a quantum-well, wherein the contents of In and Ga in the InGaN layer satisfy a relation of In/(In+Ga)≧0.9. With this configuration, it is possible to efficiently generate induced emission light.

The relation of In/(In+Ga)≧0.9 regarding the contents of In and Ga in the InGaN layer is effective not only for optical pumping but also for enhancement of the luminous efficiency of the semiconductor light emitting device. From this viewpoint, according to a second aspect of the present invention, there is provided a semiconductor light emitting device including an active layer including an InGaN layer, the active layer being formed on a tilt crystal, wherein the contents of In and Ga in the InGaN layer satisfy a relation of In/(In+Ga)≧0.9.

According to a third aspect of the present invention, there is provided a semiconductor laser device having a polygonal pyramid shape. A so-called pyramid shaped semiconductor laser device has not been proposed until now, and is originally realized by the present invention.

According to a fourth aspect of the present invention, there is provided a light emitting apparatus including an array of a plurality of the above-described semiconductor light emitting devices or semiconductor laser devices. Such a light emitting apparatus allows so-called planar light emission. In particular, the light emitting apparatus configured as a semiconductor laser device including an array of the semiconductor laser devices is capable of improving a planar light emission characteristic.

### BRIEF DESCRIPTION OF THE DRAWINGS

These and other objects, features and advantages of the present invention will be apparent from the following description taken in connection with the accompanying drawings wherein:

FIGS. 1A and 1B are a schematic sectional view and a schematic plan view showing one example of a semiconductor light emitting device of the present invention, respectively;

FIG. 2 is a typical view showing the state of light emission in the semiconductor light emitting device of the present invention;

FIG. 3 is a schematic perspective view showing a first shape example of the semiconductor light emitting device of the present invention;

FIG. 4 is a schematic perspective view showing a second shape example of the semiconductor light emitting device of the present invention;

FIG. 5 is a schematic perspective view showing a third shape example of the semiconductor light emitting device of the present invention;

FIG. 6 is a schematic perspective view showing a fourth shape example of the semiconductor light emitting device of the present invention;

FIG. 7 is a schematic perspective view showing a fifth shape example of the semiconductor light emitting device of the present invention;

FIG. 8 is schematic perspective view showing one example of an S-plane type semiconductor laser device of the present invention;

FIG. 9 is a schematic perspective view showing one example of a light emitting apparatus allowing planar light emission;

FIG. 10 is a perspective view showing a schematic configuration of a stripe shaped semiconductor light emitting device fabricated according to the present invention;

FIG. 11 is a characteristic diagram showing an emission spectrum of the stripe shaped semiconductor light emitting device fabricated according to the present invention;

FIG. 12 is a perspective view showing a schematic configuration of a pyramid shaped semiconductor light emitting device fabricated according to the present invention; and

FIG. 13 is a characteristic diagram showing an emission spectrum of the pyramid shaped semiconductor light emitting device fabricated according to the present invention.

### DETAILED DESCRIPTION OF THE PREFERRED EMBODIMENTS

Hereinafter, a semiconductor light emitting device, a semiconductor laser device, and a light emitting apparatus, to each of which the present invention is applied, will be described in detail with reference to the drawings.

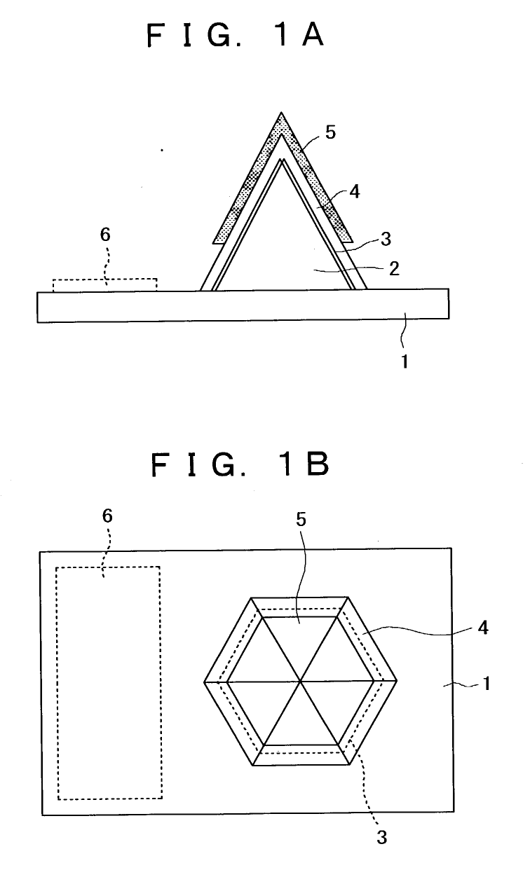

The semiconductor light emitting device to which the present invention is applied will be described with reference to FIGS. 1A and 1B.

FIGS. 1A and 1B are a sectional view and a plan view showing a typical structure of the semiconductor light emitting device to which the present invention is applied, respectively.

The light emitting device shown in the figures is exemplified by a GaN based light emitting diode, which is formed by crystal growth on, for example, a sapphire substrate. Such a GaN based light emitting diode formed on the sapphire substrate has a feature that it can be easily peeled from the sapphire substrate by laser irradiation. More specifically, when an interface between the sapphire substrate and a GaN based growth layer of the GaN based light emitting diode is irradiated with laser beams passing through the sapphire substrate, laser abrasion occurs at the interface, to cause film peeling at the interface by a phenomenon that nitrogen (N) of GaN is vaporized.

The GaN based light emitting diode shown in the figures has a structure that a hexagonal pyramid shaped GaN layer 2 is formed by selective crystal growth on an underlying growth layer 1 made from a GaN based semiconductor. While not shown, an insulating film having an opening is formed as a mask on the underlying growth layer 1, and the hexagonal pyramid shaped GaN layer 2 is formed by selective crystal growth from the opening of the insulating film by an MOCVD process or the like. If the C-plane of sapphire is used as the principle plane of the sapphire substrate for forming the GaN layer 2 thereon by crystal growth, the GaN layer 2 becomes a growth layer having a pyramid shape covered with an S-plane, that is, (1-101) plane. The GaN layer 2 is a region doped with silicon. The tilt S-plane portion of the GaN layer 2 is made n-type conductive and functions as a cladding portion of a double-hetero structure.

An active layer 3 made from InGaN is formed so as to cover the tilt S-plane of the GaN layer 2. The active layer 3 may be a single layer, or a layer having a multi-quantum well (MQW) structure.

If the GaN based light emitting diode includes the active layer 3 having the MQW structure, it allows efficient light emission.

The active layer 3 having the MQW structure may be formed, for example, by repeatedly stacking units each having an InGaN layer as a quantum well and an GaN layer containing no indium (In) (or containing In in an amount different from that of In in the InGaN layer) as a barrier. The thickness of each of the quantum well and the barrier may be suitably selected (in general, to about several nm), and the number of times of repeated stacking may be suitably selected.

With respect to the InGaN layer, the content of In is important. By making the content of In larger than that in an InGaN layer of a related art active layer, it is possible to realize efficient light emission by optical pumping. To be more specific, the contents of In and Ga are required to satisfy a relation of In/(In+Ga)≧0.9.

A p-type GaN layer 4 is formed on the outer surface of the active layer 3. The p-type GaN layer 4 also functions as a cladding portion.

The light emitting diode has a p-electrode 5 and an n-electrode 6. A metal material such as Ni/Pt/Au or Ni(Pd)/Pt/Au is vapor-deposited on the p-type GaN layer 4, to form the p-electrode 5. A metal material such as Ti/Al/Pt/Au is vapor-deposited in an opening formed in the above-described insulating film (not shown), to form the n-electrode 6. In the case of extracting an n-electrode from the back surface side of the underlying growth layer 1, it is not required to form the n-electrode 6 on the front surface side of the underlying growth layer 1.

The semiconductor light emitting device of the present invention configured as described above is characterized by generating induced emission light by light irradiation.

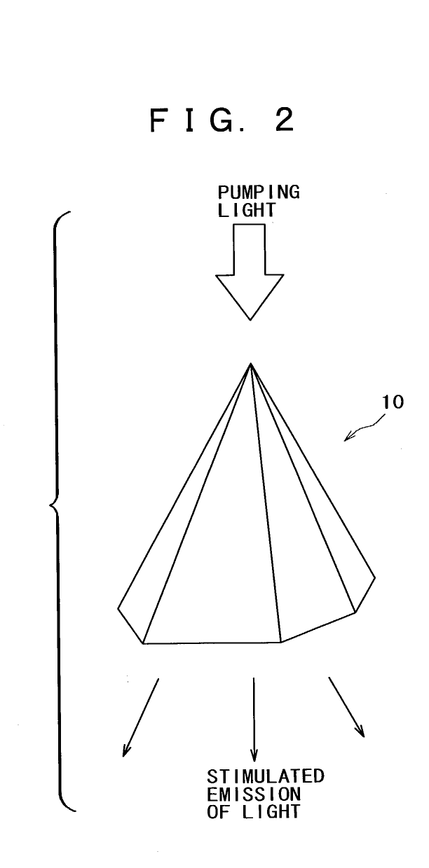

An ordinary semiconductor light emitting device emits light only by injection of electric charges. On the other hand, as shown in FIG. 2, when irradiated with pumping light, the semiconductor light emitting device of the present invention, denoted by reference numeral 10 in the figure, generates induced emission light by optical pumping. In actual, the present inventors have experimentally confirmed that the semiconductor light emitting device of the present invention generates induced emission light having a wavelength of about 400 nm when irradiated with light having a wavelength of 355 nm.

The light emission by optical pumping is considered to be equivalent to so-called super luminescence. The semiconductor light emitting device of the present invention, therefore, can be regarded as a super luminescent diode. In particular, if the semiconductor light emitting device of the present invention has a resonance structure allowing laser oscillation, it functions as a laser diode.

The semiconductor light emitting device of the present invention allows light emission not only by optical pumping but also by injection of electric charges or a combination of optical pumping and injection of electric charges. In particular, by adopting the combination of optical pumping and injection of electric charges, it is possible to significantly improve the luminous efficiency of the semiconductor light emitting device.

The configuration of the above-described semiconductor light emitting device will be described in more detail below. As described above, the semiconductor light emitting device to which the present invention is applied is represented by a semiconductor light emitting device fabricated by forming, on a substrate, a crystal layer having a tilt crystal plane (for example, S-plane) tilted from the principal plane of the substrate, and sequentially forming a first conductive type layer, an active layer, and a second conductive type layer in such a manner that each of these layers extends within a plane parallel to the tilt crystal plane of the crystal layer.

The substrate used herein is not particularly limited insofar as it allows a crystal layer having a tilt crystal plane tilted from the principal plane of the substrate to be formed thereon, and may be selected from various substrates, for examples, substrates made from sapphire (Al₂O₃, having A-plane, R-plane, or C-plane), SiC (including 6H, 4H, and 3C), GaN, Si, ZnS, ZnO, AlN, LiMgO, GaAs, MgAl₂O₄, and InAlGaN. Of these substrates, hexagonal or cubic crystal based substrates are preferred, with the hexagonal substrates being most preferred.

In the case of using a sapphire substrate, the C-plane of sapphire may be taken as the principal plane of the substrate. In general, the sapphire substrate with the C-plane of sapphire taken as the principal plane thereof has been often used to grow a gallium nitride (GaN) based compound semiconductor thereon. It is to be noted that the C-plane of sapphire taken as the principal plane of the sapphire substrate is not limited to the theoretical C-plane but may be a plane tilted from the theoretical C-plane by an angle 5 to 6 degrees.

The substrate may not be a constituent of a light-emitting device as a product. In other words, the substrate may be used merely to hold a device portion and be removed before the device is accomplished.

The crystal layer formed on the substrate has a tilt crystal plane tilted from the principal plane of the substrate. The crystal layer is not particularly limited insofar as it allows a light-emitting region (to be described later) composed of a first conductive type layer, an active layer, and a second conductive type layer to be form on a plane parallel to the tilted crystal plane, tilted from the principal plane of the substrate, of the crystal layer. In general, the crystal layer is preferably made from a material having a wurtzite type crystal structure.

For example, such a crystal layer may be made from a material selected from a group III based compound semiconductor, a BeMgZnCdS based compound semiconductor, a BeMgZnCdO based compound semiconductor, a gallium nitride (GaN) based compound semiconductor, an aluminum nitride (AlN) based compound semiconductor, an indium nitride (InN) based compound semiconductor, an indium gallium nitride (InGaN) based compound semiconductor, and an aluminum gallium nitride (AlGaN) based compound semiconductor. Of these materials, a nitride semiconductor such as a gallium nitride based compound semiconductor is preferably used as the material for forming the crystal layer.

It is to be noted that according to the present invention, the nitride semiconductor expressed by InGaN, AlGaN, or GaN does not necessarily mean only InGaN, AlGaN, or GaN in the form of a strict ternary or binary mixed crystal. For example, the nitride semiconductor expressed by InGaN may contain a trace amount of Al and other impurities which do not affect the function of InGaN without departing from the scope of the present invention.

The crystal layer can be formed by a chemical vapor deposition process selected, for example, from a metal organic chemical vapor deposition (MOCVD) process including a metal organic vapor phase epitaxy (MOVPE) process, a molecular beam epitaxy (MBE) process, and a hydride vapor phase epitaxy (HVPE) process. In particular, the MOCVD process is preferred because it rapidly yields a crystal layer with a desirable crystallinity. The MOCVD method commonly employs alkyl metal compounds, such as TMG (trimethylgallium) or TEG (triethylgallium) as a Ga source, TMA (trimethylaluminum) or TEA (triethylaluminum) as an Al source, and TMI (trimethylindium) or TEI (triethylindium) as an In source. It also employs ammonia gas or hydrazine gas as a nitrogen source, and other gases as an impurity source, for example, silane gas for Si, germane gas for Ge, Cp₂Mg (cyclopentadienylmagnesium) for Mg, and DEZ (diethylzinc) for Zn. In the general MOCVD process, the gases are fed to the surface of the substrate heated at about 600° C. or more, and are decomposed to form a layer of an InAlGaN based compound semiconductor by epitaxial growth.

It is preferred to form an underlying growth layer on the substrate and to form the crystal layer on the underlying growth layer.

The underlying growth layer can be formed by the same chemical vapor deposition process as that used for forming the crystal layer, for example, the metal organic chemical vapor deposition (MOCVD) process, molecular beam epitaxy (MBE) process, or hydride vapor phase epitaxy (HVPE) process.

The underlying growth layer may be made from, for example, gallium nitride or aluminum nitride, and may have a structure composed of a combination of a low-temperature buffer layer and a high-temperature buffer layer, or a combination of a buffer layer and a crystal seed layer functioning as a crystal seed.

The above structure of the underlying growth layer will be described in detail below.

If the crystal layer is formed by crystal growth from a low-temperature buffer layer, there occurs a problem that polycrystals tend to be deposited on the mask layer. To solve such a problem, a high-temperature buffer layer may be formed on the low-temperature buffer layer and then the crystal layer be formed thereon so as to be grown along a plane different from the principal plane of the substrate. With this configuration, the crystal layer with a desirable crystallinity can be formed by crystal growth.

In the case of using no crystal seed layer at the time of forming the crystal layer, the crystal layer is required to be formed by selective crystal growth from a buffer layer. At this time, however, there occurs a problem that crystal growth is liable to occur even in an anti-growth region where the crystal growth is not required. To solve such a problem, a crystal seed layer may be formed on the buffer layer and the crystal layer be formed by selective crystal growth from the crystal seed layer. With this configuration, the crystal layer can be selectively formed in a region where the crystal growth is required.

The low-temperature buffer layer is intended to relieve lattice mismatch between the substrate and a nitride semiconductor. Accordingly, if the substrate has a lattice constant close to or identical to that of a nitride semiconductor, the low-temperature buffer layer is not necessarily provided. For example, an AlN layer may be grown on an SiC substrate as a high-temperature buffer layer without lowering the growth temperature, and an AlN or GaN layer may be grown on an Si substrate as a high-temperature buffer layer without lowering the growth temperature. Even in this case, a GaN layer with a desirable crystallinity can be formed by crystal growth on the buffer layer. Additionally, in the case of using a GaN substrate, the structure without any buffer layer may be adopted.

In fabrication of the semiconductor light emitting device according to this embodiment, the crystal layer having a tilt crystal plane tilted from the principal plane of the substrate is formed by using the selective growth process.

The tilt crystal plane, tilted from the principal plane of the substrate, of the crystal layer is grown depending on the kind of the principal plane of the substrate.

If the crystal layer is grown on the (0001) plane [C-plane] as the principal plane of the substrate having the wurtzite type crystal structure, the tilt crystal plane of the crystal layer becomes one selected from the (1-100) plane [M-plane], the (1-101) plane [S-plane], the (11-20) plane [A-plane], the (1-102) plane [R-plane], the (1-123) plane [N-plane], the (11-22) plane, and crystal planes equivalent thereto. In particular, it is preferred to grow the crystal layer with the S-plane or the (11-22) plane, or the crystal plane equivalent thereto. It is to be noted that the crystal plane equivalent to the S-plane or the (11-22) plane is the crystal plane tilted from the S-plane or the (11-22) plane by an angle of 5 to 6 degrees.

In particular, the S-plane is a stable plane selectively grown on the C⁺-plane and is therefore relatively obtainable. The S-plane is expressed by the (1-101) plane in accordance with Miller indices of a hexagonal crystal system. Just as the C-plane includes the C⁺-plane and the C⁻-plane, the S-plane includes the S⁺-plane and the S⁻-plane. In this specification, the S⁺-plane is grown on the C⁺-plane of GaN, and it is referred to as the S-plane unless otherwise stated. Of the S-planes, the S⁺-plane is stable. In addition, the Miller index of the C⁺-plane is (0001).

In the case of growing the S-plane of the crystal layer made from a gallium nitride based compound semiconductor on the C⁺-plane of the substrate as described above, the number of bonds from Ga to N on the S-plane is 2 or 3, which number is second to that on the C-plane. Since the C⁻-plane cannot be grown on the C⁺-plane in practice, the number of bonds on the S-plane is the largest.

In the case of growing a wurtzite type nitride, for example, GaN based nitride on a sapphire substrate with the C-plane of sapphire taken as the principal plane thereof, if the selective growth process is not used to grow the nitride, the surface of the nitride is grown as the C⁺-plane, whereas if the selective growth process is used to grow the nitride, the surface of the nitride can be grown as the S-plane tilted from the C-plane of the sapphire substrate.

On the C⁺-plane, parallel to the C-plane of the substrate, of the nitride, the bond of N liable to be easily released from the plane combines with one bond of Ga, whereas on the S-plane, tilted from the C-plane of the substrate, of the nitride, the bond of N combines with at least one bond of Ga.

As a result, the V/III ratio of the nitride grown along the S-plane can be effectively increased, to advantageously improve the crystallinity of the laminated structure. In addition, according to the formation of the nitride by the selective growth process, since nitride is grown along the S-plane different from the orientation of the substrate, dislocations extending upwardly from the substrate may be bent, to advantageously reduce crystal defects of the nitride.

In the semiconductor light emitting device according to this embodiment, as described above, the crystal layer has a tilt crystal plane tilted from the principal plane of the substrate.

The structure of the crystal layer will be more fully described below.

The crystal layer may have an approximately hexagonal pyramid shape in which the tilt plane forming the pyramid shape is composed of the S-plane or a plane substantially equivalent thereto. Alternatively, the crystal layer may have a so-called approximately hexagonal truncated pyramid shape in which the tilt plane of the truncated pyramid shape is composed of the S-plane or a plane substantially equivalent thereto, and the upper flat plane of the truncated pyramid shape is composed of the C-plane or a plane substantially equivalent thereto.

Each of the approximately hexagonal pyramid shape and the approximately hexagonal truncated pyramid shape is not necessarily a perfect hexagonal shape but may be an imperfect hexagonal shape with one or more missing faces.

In a preferred embodiment, the tilt crystal plane is hexagonal and is arranged so as to be approximately symmetrical. The term “approximately symmetrical” used herein embraces not only completely symmetrical but also slightly asymmetrical.

The ridge between adjacent two crystal plane segments of the crystal layer is not necessarily a straight line. Also, each of the approximately hexagonal pyramid shape and the approximately hexagonal truncated pyramid shape may extend in straight line.

The concrete selective growth process used for selectively growing the crystal layer will be described below.

The selective growth of the crystal layer is performed by making use of a selectively removed portion of the underlying growth layer, or by making use of a selectively formed opening in a mask layer which is formed on or under the underlying growth layer.

For example, if the underlying growth layer is composed of a buffer layer and a crystal seed layer, the crystal seed layer is formed on the buffer layer in such a manner as to be divided into scattered small regions each having a diameter of about 10 μm, and the crystal layer having the S-plane or the like is formed by crystal growth from each of the small regions. For example, the divided regions of the crystal seed layer may be arranged so as to be spaced from each other at intervals of a value equivalent of a margin for separation of adjacent light emitting devices. The divided small region may be formed into a shape selected from a stripe, a lattice, a circle, a square, a hexagon, a triangle, a rectangle, a rhombus, and other shapes deformed therefrom.

The selective growth of the crystal layer may be performed by forming a mask layer on the underlying growth layer, and selectively forming window regions in the mask layer. The mask layer may be made from silicon oxide or silicon nitride. The crystal layer having an approximately hexagonal truncated pyramid shape or an approximately hexagonal pyramid shape extending in straight line in one longitudinal direction as described above can be formed by selective crystal growth from each of stripe-shaped window regions formed in the mask layer or from each of stripe-shaped regions of the crystal seed layer.

By forming, in the mask layer, the window region of a circular shape (or a hexagonal shape whose one side extends along the (1-100) direction or (11-20) direction) having a size of around 10 μm, it is possible to easily form the crystal layer having a size of about twice as large as the window region by selective growth from the window region. In the crystal layer thus formed by selective growth, since the S-plane tilted from the principal plane of the substrate has an effect of bending and blocking dislocations extending from the substrate, it is possible to reduce the density of dislocations in the crystal layer.

The present inventors have made an experiment to examine characteristics of the S-plane of a semiconductor light emitting device.

A semiconductor light emitting device was prepared by forming a crystal layer of a hexagonal truncated pyramid shape having the S-plane by selective growth, and sequentially growing an InGaN active layer and a Mg-doped layer on the S-plane of the crystal layer.

With respect to such a semiconductor light emitting device, the state of each layer grown along the S-plane was examined.

As a result of observation of the state of the S-plane by making use of cathode luminescence, it was revealed that the crystallinity of the S-plane is desirable, and therefore, the luminous efficiency on the S-plane is higher than that on the C⁺-plane.

In particular, since the growth temperature of the InGaN active layer is in a range of 700 to 800° C., the decomposition efficiency of ammonia is low, with a result that the growth of the InGaN active layer requires a larger amount of nitrogen species. In this regard, the growth of the InGaN active layer on the S-plane is preferred. As a result of observation of the surface state of the S-plane by AFM (Atomic Force Microscopy), it was revealed that the surface state of the S-plane is a regular stepped state suitable for growth of InGaN thereon.

As a result of observation by AFM, it was also revealed that although the state of the growth surface of the Mg-doped layer is generally poor in the level observed by AFM, the Mg-doped layer can be grown along the S-plane while keeping a desirable surface state, and that the doping condition at the time of growth on the S-plane is quite different from that at the time of growth on a plane other than the S-plane.

The S-plane was further subjected to microscopic photoluminescence mapping having a resolving power of about 0.5 to 1 μm. The result showed that although the surface of the sample grown on the C⁺-plane by the ordinary growth process has irregularities at a pitch of about 1 μm, the surface of the sample grown on the S-plane is uniform.

In addition, as a result of observation of SEM (scanning electron microscope), it was revealed that the flatness of the tilt plane of the layer grown on the S-plane obtained by the selective growth process is smoother than the flat plane of the layer grown along the C⁺-plane obtained by the ordinary growth process.

In the case of forming a crystal layer by selective growth from a window region formed in a selective growth mask, the crystal layer is generally grown only in an area over the window region. In this case, to realize lateral growth of the crystal layer, there may be adopted a micro-channel epitaxy process. The use of the micro-channel epitaxy process allows the crystal layer to be laterally grown into a shape larger than the window region.

It is known that the lateral growth of the crystal growth by using the micro-channel epitaxy process is effective to prevent threading dislocations extending from the substrate from being propagated in the crystal layer and hence to reduce the density of dislocations in the crystal layer. The lateral growth of the crystal layer by using the micro-channel epitaxy process is also advantageous in increasing the light-emitting region, equalizing a current, avoiding concentration of current, and reducing the current density.

In the semiconductor light emitting device according to this embodiment, as described above, a crystal layer having a tilt crystal plane tilted from the principal plane of a substrate is formed, and a first conductive type layer, an active layer, and a second conductive type layer are sequentially formed on the crystal layer so as to extend within planes parallel to the tilt crystal plane, tilted from the principal plane of the substrate, of the crystal layer.

The first conductive type layer is a p-type or n-type cladding layer, and the second conductive type layer is an n-type or p-type cladding layer.

For example, in the case of forming the crystal layer having the S-plane by using a gallium nitride based compound semiconductor, the n-type cladding layer made from a silicon-doped gallium nitride based compound semiconductor may be formed on the S-plane of the crystal layer, an active layer made from InGaN be formed on the n-type cladding layer, and the p-type cladding layer made from magnesium-doped gallium nitride based compound semiconductor be formed on the active layer. The semiconductor light emitting device thus produced has a so-called double-hetero structure.

The active layer may have a structure that an InGaN layer be sandwiched between AlGaN layers. Also, the active layer may be of a single bulk layer structure, or a quantum well structure such as a single quantum well (SQW) structure, a double quantum well (DQW) structure, or multiple quantum well (MQW) structure. The quantum well structure uses a barrier layer for separation of quantum wells, if necessary.

The provision of the InGaN layer as the active layer is particularly advantageous in terms of easy fabrication of the light emitting device and improvement of light emission characteristics of the light emitting device. The InGaN layer grown on the S-plane is further advantageous in that since the S-plane has a structure that nitrogen atoms are less releasable, the crystallization of InGaN on the S-plane is particularly easy and the crystallinity of InGaN formed on the S-plane is desirable. Further, as described above, it is important that the contents of In and Ga are set to satisfy the relation of In/(In+Ga)≧0.9.

Additionally, a nitride semiconductor has a property to become n-type conductive even in the non-doped state because of nitrogen holes occurring in crystal; however, the nitride semiconductor may be converted into an n-type semiconductor with a desirable concentration of carriers by doping an ordinary donor impurity such as Si, Ge, or Se during crystal growth of the nitride semiconductor.

A nitride semiconductor can be converted into a p-type semiconductor by doping an acceptor impurity such as Mg, Zn, C, Be, Ca, or Ba in crystal of the nitride semiconductor. In this case, to obtain a p-layer with a high carrier density, after being doped with the acceptor impurity, the nitride semiconductor may be activated, for example, by an annealing treatment performed at about 400° C. or more in an inert gas atmosphere such as a nitrogen or argon atmosphere. The activation of the nitride semiconductor may be performed by irradiating the nitride semiconductor with electron beams, microwaves, or light.

The first conductive type layer, the active layer, and the second conductive type layer can be easily formed on the crystal layer so as to extend within planes parallel to the tilt crystal plane, tilted from the principal plane of the substrate, of the crystal layer by continuously forming these layers on the tilt crystal plane of the crystal layer by crystal growth. If the crystal layer has an approximately hexagonal pyramid or approximately hexagonal truncated pyramid shape whose tilt crystal plane is the S-plane, the light emission region composed of the first conductive type layer, the active layer, and the second conductive type layer can be wholly or partially formed on the S-plane. If the crystal layer has an approximately hexagonal truncated pyramid shape, the first conductive type layer, the active layer, and the second conductive type can be formed even on an upper plane, parallel to the principal plane of the substrate, of the truncated pyramid shape.

In the case of forming the light emission region on the plane parallel to the principal plane of the substrate, light emitted from the light emission region is decayed by multiple reflection, whereas in the case of forming the light emission region on the tilt S-plane tilted from the principal plane of the substrate, light emitted from the light emission region can be emerged to the outside of the light emitting semiconductor device without occurrence of multiple reflection.

The first conductive type layer functioning as the cladding layer can be made from the same material as that of the crystal layer so as to have the same conductive type as that of the crystal layer. To be more specific, the first conductive type layer can be formed by continuing, after the crystal layer having the S-plane is formed, the crystal growth while continuously adjusting the concentration of the source gas. Alternatively, the first conductive type layer may be configured as part of the crystal layer having the S-plane. In addition, to improve the light emergence efficiency, the first conductive type layer may be formed on the plane not parallel to the principal plane of the substrate.

According to the semiconductor light emitting device in this embodiment, the luminous efficiency can be increased by making use of a desirable crystallinity of the tilt crystal plane, tilted from the principal plane, of the crystal layer. In particular, by injecting a current only into the S-plane having a desirable crystallinity, it is possible to enhance the luminous efficiency. This is because the InGaN active layer can be desirably formed on the S-plane having a desirable crystallinity. In addition, the actual area of the active layer extending within a plane being substantially parallel to the S-plane is larger than the area, projected on the principal plane of the substrate or the underlying growth layer, of the active layer. The enlarged area of the active layer makes it possible to increase the area of the light emission region of the device and thereby reduce the density of a current injected in the light emission region, and to reduce the saturated luminance and thereby increase the luminous efficiency.

With respect to the semiconductor light emitting device including the hexagonal pyramid shaped crystal layer having the tilt S-plane, the stepped state of the surface of a portion near the top of the S-plane becomes poor, so that the luminous efficiency at the top portion of the device is degraded.

To be more specific, when the S-plane section on one side of the hexagonal pyramid shape is divided into four regions (top region, left region, right region, and bottom region) with respect to a nearly central portion of the S-plane section, the stepped state is most wavy in the top region, whereby abnormal crystal growth is liable to occur in the top region. On the contrary, in each of the left and right regions, since steps extend nearly in straight line and are closely collected, the crystal growth state becomes desirable. In the bottom region, although steps are slightly wavy, crystal growth is not so abnormal as observed in the top region.

In the semiconductor light emitting device of the present invention, it is thus recommended that the injection of a current in the active layer be controlled such that the current density in the top region be smaller than that in each of the other regions. To make the current density in the top region small, an electrode may be formed not in the top region but in the side region, or a current blocking area be formed in the top region before an electrode is formed in the top region.

An electrode is formed on each of the crystal layer and the second conductive type layer. To reduce the contact resistance, a contact layer may be formed and then the electrode be formed thereon. In the case of forming these electrodes by vapor deposition, if the p-electrode and the n-electrode adhere on both the crystal layer and the crystal seed layer formed under the mask layer, there occurs short-circuit therebetween. To cope with such an inconvenience, each of the electrodes must be accurately formed by vapor deposition.

An image display unit or an illumination unit can be fabricated by arraying a plurality of the semiconductor light emitting devices according to the present invention. In this case, according to the semiconductor light emitting device of the present invention, the electrode area can be suppressed by making use of the S-plane, and accordingly, by preparing the semiconductor light emitting devices of three primary colors and arraying them in a scannable manner, an image display unit with a reduced electrode area can be realized.

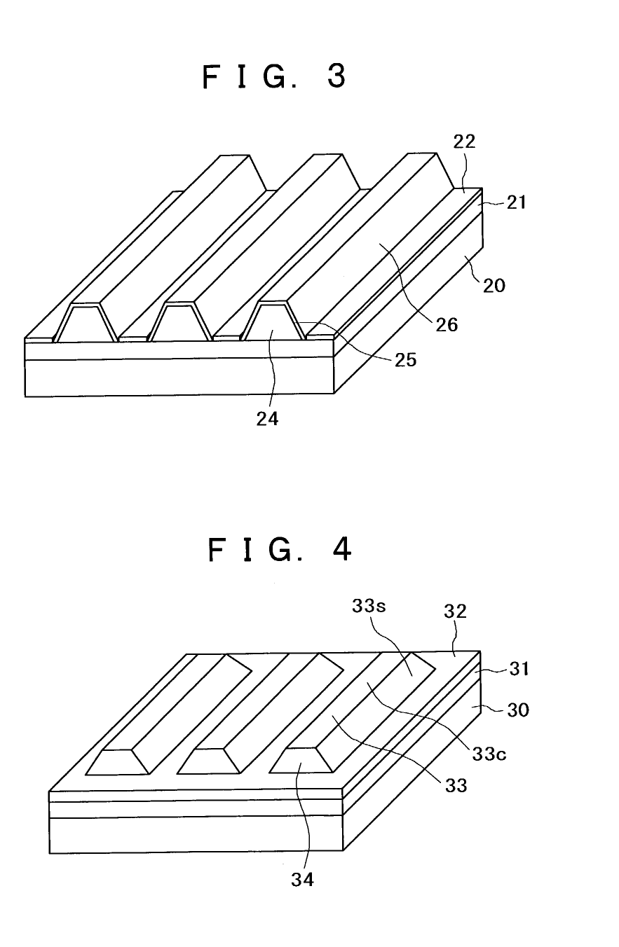

The shape of the semiconductor light emitting device of the present invention can be variously changed as described below with reference to examples shown in FIGS. 3 to 7.

FIG. 3 shows a first example in which each stripe-shaped crystal growth layer is formed on a growth substrate. As shown in the figure, an underlying growth layer 21 is formed on a growth substrate 20, a mask layer 22 having window regions is formed on the underlying growth layer 21, and stripe-shaped crystal growth layers 24 are formed by selective crystal growth from the window regions. In the stripe-shaped crystal growth layer 24, both side surfaces 26 are each taken as the S-plane. An active layer 25 is formed on each crystal growth layer 24 in such a manner as to extend on both the tilt side surfaces 26 and an upper surface of the crystal growth layer 24. The area of the active area 25 is larger than the area, projected on the horizontal plane, of the crystal growth layer 24. As a result, it is possible to effectively relieve the saturated luminance and hence to improve the reliability of the device.

FIG. 4 shows a second example in which each rectangular trapezoidal crystal growth layer is formed on a growth substrate. As shown in the figure, an underlying growth layer 31 is formed on a growth substrate 30, a mask layer 32 having window regions is formed on the underlying growth layer 31, and stripe-shaped rectangular trapezoidal crystal growth layers 33 are formed by selective growth from the window regions. In the rectangular trapezoidal crystal growth layer 33, both side surfaces 33S are each taken as the S-plane, both longitudinal end surfaces 34 are each taken as the (11-22) plane, and an upper surface 33C is taken as the C-plane being the same as that of the principal plane of the growth substrate 30. While not shown, an active layer is formed on each crystal growth layer 33 in such a manner as to extend on the tilted side surfaces 33S, the end surfaces 34, and the upper surface 33C. The area of the active layer is larger than the area, projected on the horizontal plane, of the crystal growth layer 33. As a result, it is possible to effectively relieve the saturated luminance and hence to improve the reliability of the device.

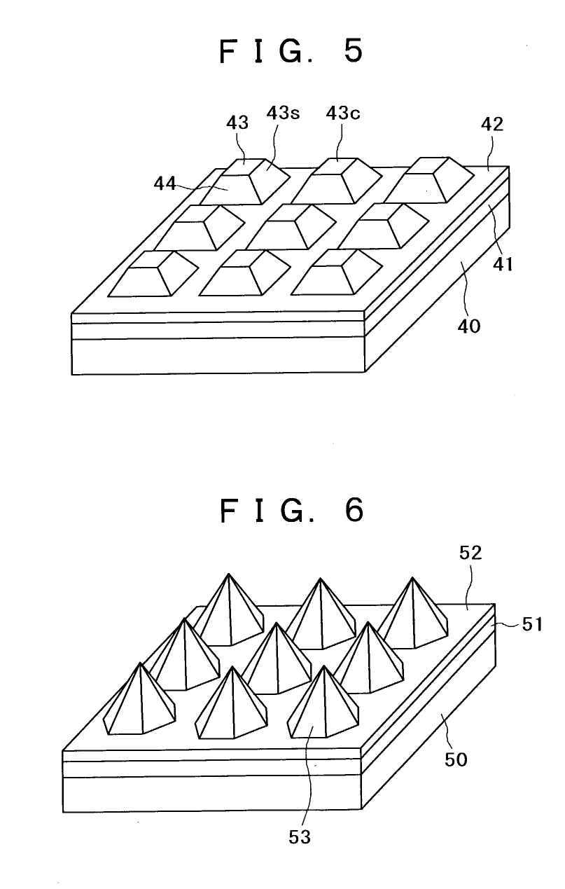

FIG. 5 shows a third example in which each square truncated pyramid shaped crystal growth layer is formed on a growth substrate. As shown in the figure, an underlying growth layer 41 is formed on a growth substrate 40, a mask layer 42 having window regions is formed on the underlying growth layer 41, and square truncated pyramid shaped crystal growth layers 43 are formed by selective crystal growth from the window regions in such a manner as to be arrayed in a matrix pattern. In the square truncated pyramid shaped crystal growth layer 43, a pair of opposed tilt side surfaces 43S are each taken as the S-plane, another pair of opposed tilt side surfaces 44 are each taken as the (11-22) plane, and an upper surface 43C is taken as the C-plane being the same as that of the principal plane of the growth substrate 40. While not shown, an active layer is formed on each crystal growth layer 43 in such a manner as to extend on the tilted side surfaces 43S and 44, and the upper surface 43C. The area of the active layer is larger than the area, projected to horizontal plane, of the crystal growth layer 43. As a result, it is possible to effectively relieve the saturated luminance and hence to improve the reliability of the device.

FIG. 6 shows a fourth example in which each hexagonal pyramid shaped crystal growth layer is formed on a growth substrate. As shown in the figure, an underlying growth layer 51 is formed on a growth substrate 50, a mask layer 52 having window regions is formed on the underlying growth layer 51, and hexagonal pyramid shaped crystal growth layers 53 are formed by selective crystal growth from the window regions in such a manner as to be arrayed in a matrix pattern. In the hexagonal pyramid shaped crystal growth layer 53, side surfaces are each taken as the S-plane. While not shown, an active layer is formed on each crystal growth layer 53 in such a manner as to extend on the tilt S-planes. The area of the active layer is larger than the area, projected to horizontal plane, of the crystal growth layer 53. As a result, it is possible to effectively relieve the saturated luminance and hence to improve the reliability of the device.

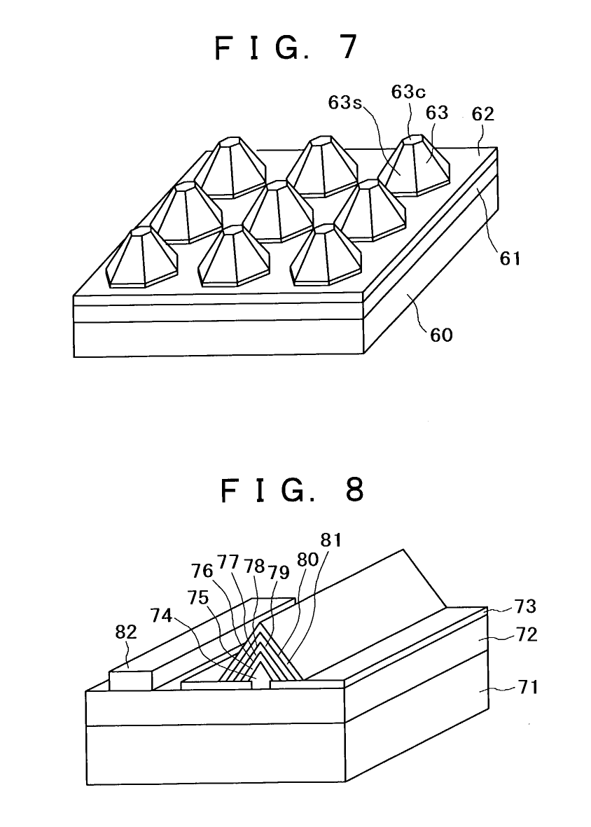

FIG. 7 shows a fifth example in which each hexagonal truncated pyramid shaped crystal growth layer is formed on a growth substrate. As shown in the figure, an underlying growth layer 61 is formed on a growth substrate 60, a mask layer 62 having window regions is formed on the underlying growth layer 61, and hexagonal truncated pyramid shaped crystal growth layers 63 are formed by selective crystal growth from the window regions in such a manner as to be arrayed in a matrix pattern. In the hexagonal truncated crystal growth layer 63, side surfaces 63S are each taken as the S-plane, and an upper surface 63C is taken as the C-plane being the same as that of the principal plane of the substrate. In addition, a small-height portion having the M-plane, that is, the (1-100) plane is also formed on the bottom surface side of the hexagonal truncated pyramid shaped crystal growth layer 63. While not shown, an active layer is formed on each crystal growth layer in such a manner as to extend on the tilt S-planes and the C-plane. The area of the active layer is larger than the area, projected to the horizontal plane, of the crystal growth layer 63. As a result, it is possible to effectively relieve the saturated luminance and hence to improve the reliability of the device.

The semiconductor light emitting device of the present invention can be, as described above, configured as a laser diode. Such a laser diode to which the present invention is applied will be described below. One example of the laser diode used for the following description is an S-plane type semiconductor laser device in which respective layers are grown on the (1-101) plane, that is, the S-plane, and more specifically, a cladding layer, a guide layer, and an active layer are stacked on a tilt plane (S-plane) of a nitride semiconductor formed by selective growth.

As shown in FIG. 8, an S-plane semiconductor laser device to which the present invention is applied is fabricated by forming an underlying layer 72 on a substrate 71, forming a nitride semiconductor, for example, GaN:Si on the underlying layer 72 via a mask layer 73 by selective growth, to form a triangular prism shaped selective growth layer 74 having a tilt plane (S-plane), and stacking, on the selective growth layer 74, an n-type cladding layer 75, an n-type guide layer 76, an active layer 77, a p-type guide layer 78, a p-type cladding layer 79, a contact layer 80, and a p-electrode 81. An n-electrode 82 is formed in a region, where the selective growth layer 74 is not formed, of the underlying layer 72. In the n-electrode 82 formation region, the mask layer 73 is removed to expose the underlying layer 72, whereby the n-electrode 82 is directly connected to the underlying layer 72.

In addition, the substrate 71, the selective growth layer 74, the method of growing the selective growth layer 74, the underlying layer 72, and the like are the same as those used for the above-described semiconductor light emitting device.

The selective growth of the selective growth layer 74 is performed by making use of an opening selectively formed in the mask layer 73 formed on the underlying layer 72 or formed before formation of the underlying layer 72. The mask layer 73 is made from, for example, silicon oxide or silicon nitride. In this embodiment, the opening formed in the mask layer 73 has a slit shape, and the triangular prism shaped selective growth layer 74 is grown along the slit. Each side tilt plane is taken as the S-plane.

The selective growth layer 74 is grown in the shape having a roof shaped upper portion, and has a triangular prism having a triangular cross-section. The n-type cladding layer 75 is grown on the S-plane of the selective growth layer 74 under a growth condition different from that for growth of the selective growth layer 74. The n-type guide layer 76 is formed on the n-type cladding layer 75.

The active layer 77 is formed on the n-type guide layer 76. The content of In in the active layer 77 made from InGaN may be higher than that in each of the above-described n-type guide layer 76 made from InGaN and the p-type guide layer 78 made from InGaN to be described later, and preferably, the content of In in the active layer 77 is set to a value more than 20 atomic %.

The p-type guide layer 78 and the p-type cladding layer 79 are sequentially stacked on the active layer 77.

By the way, a nitride semiconductor can be converted into a p-type semiconductor by doping an acceptor impurity such as Mg, Zn, C, Be, Ca, or Ba in crystal of the nitride semiconductor. In this case, to obtain a p-layer with a high carrier density, the nitride semiconductor, which has been doped with an acceptor impurity, may be activated, for example, by an annealing treatment performed at about 400° C. or more in an inert gas atmosphere such as a nitrogen or argon atmosphere. The activation of the nitride semiconductor may be performed by irradiating the nitride semiconductor with electron beams, microwaves, or light.

The contact layer 80 made from, for example, InGaN:Mg is grown on the p-type cladding layer 79. The content of In in the contact layer 80 is set, for example, to 10 atomic %. The p-electrode 81 is formed on the contact layer 80 by vapor-deposition. The p-electrode 81 is formed by a metal thin film made from Al, Ag, Au, Ti, Pt or Pd, or a stacked structure of a combination of these metal thin films. In this embodiment, the p-electrode 81 is made from a combination of Pd/Pt/Au.

The mask layer 73 is selectively etched by using hydrofluoric acid based etchant, to partially expose the underlying layer 72, and the n-electrode 82 made from Ti/Pt/Au is formed on the exposed portion of the underlying layer 72 by vapor-deposition. Finally, the stacked structure is subjected to cleavage, to form end faces for forming a resonator, thus accomplishing a semiconductor laser device.

The above-described semiconductor laser device is characterized by including at least the cladding layer, the guide layer, and the active layer, wherein the cladding layer is made from GaN, each of the guide layer and the active layer is made from InGaN, and the content of In in the active layer is higher than that in the guide layer, and is set to 20 atomic % or more. The cladding layer does not include AlGaN, that is, it is free of Al. Accordingly, it is possible to avoid occurrence of catastrophe optical damage (COD) resulting from introduction of Al, and hence to solve the problem associated with abnormal growth.

In the case of adopting the above-described structure of the semiconductor laser device, since the band gap can be changed only by the content of In, the emission wavelength can be adjusted by controlling the content of In in the active layer and the thickness of the active layer. For example, a blue light semiconductor laser device having an emission wavelength of 460 to 490 nm can be obtained by setting an energy difference between the band gap of the cladding layer and the band gap of the active layer to 0.5 eV or more, the content of In in the active layer to 20 to 30 atomic %, and the thickness of the active layer to 1 to 10 nm. A green light semiconductor laser device having an emission wavelength of 500 to 550 nm can be obtained by setting an energy difference between the band gap of the cladding layer and the band gap of the active layer to 0.5 eV or more, the content of In in the active layer to 30 to 50 atomic %, and the thickness of the active layer to 1 to 10 nm.

If the above-described semiconductor laser device includes the active layer having a multi-quantum well structure including the InGaN layers, wherein the contents of In and Ga in the active layer satisfy a relation of In/(In+Ga)≧0.9, such semiconductor laser device allows laser oscillation by optical pumping, and is therefore advantageous in realizing efficient laser oscillation.

In this embodiment, the semiconductor laser device is formed into the so-called roof top shape having a triangular cross-section; however, it can be formed into a so-called polygonal pyramid shape by adjusting the growth condition. Even the semiconductor laser device having a polygonal pyramid shape also allows oscillation by optical pumping, oscillation by injection of electric charges, or a combination thereof. The so-called pyramid type laser diode has not been proposed until now, and is originally realized by the present invention.

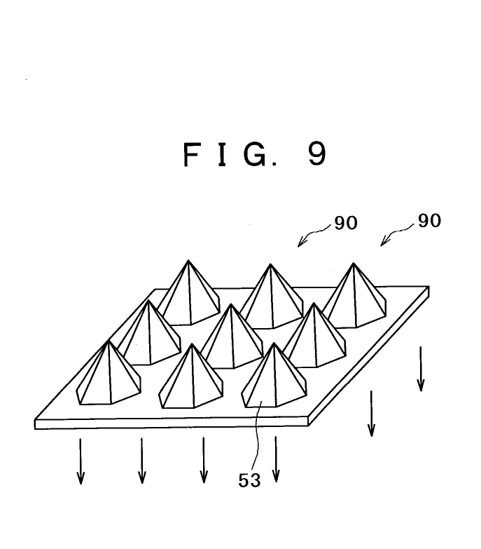

A planar light emission type light emitting apparatus can be realized by arraying, on the same plane, a plurality of the above-described semiconductor light emitting devices or semiconductor laser devices. FIG. 9 shows one example of a planar light emission type laser light emitting apparatus fabricated by arraying a plurality of pyramid type semiconductor light emitting devices 90 on a transparent substrate. This planar light emission type light emitting apparatus allows large planar light emission. In particular, by arraying a plurality of semiconductor laser diodes representative of the semiconductor light emitting devices, it is possible to realize a planar light emission type laser light emitting apparatus.

Hereinafter, specific examples of the semiconductor light emitting device of the present invention will be described on the basis of experimental results.

### EXAMPLE 1

In this example, the present invention is applied to a so-called roof top type stripe shaped semiconductor light emitting device.

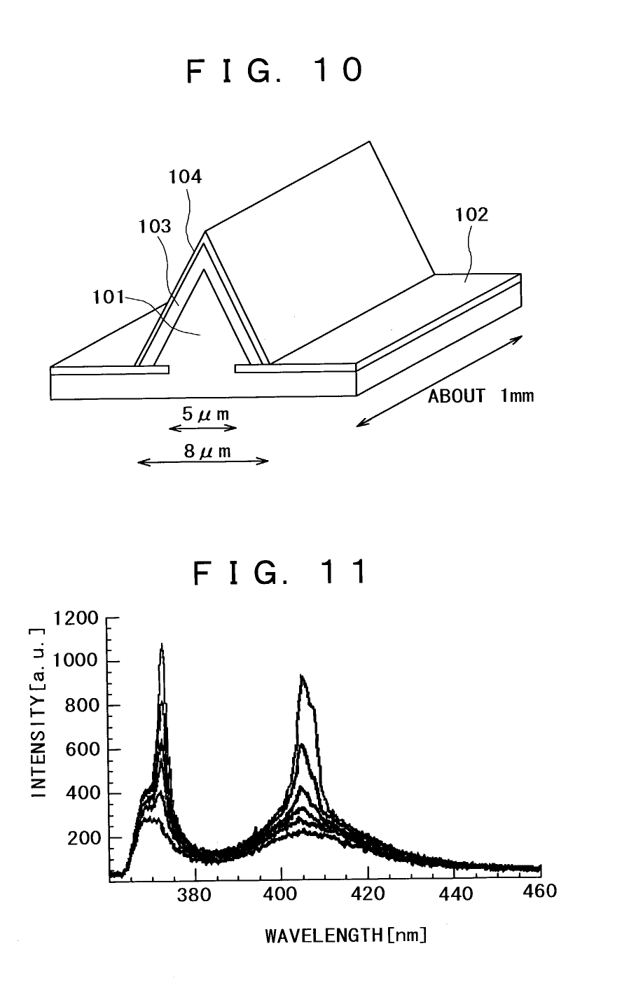

As shown in FIG. 10, a GaN layer 101 was selectively grown in the form of a roof top shape having a triangular cross-section via a mask 102, and an active layer 103 and a GaN layer 104 were selectively grown on the GaN layer 101.

The active layer 103 has a multi-quantum well (MQW) structure including 10 quantum well layers. Each quantum well was formed as an InGaN layer having a thickness of 3 nm, and each barrier was formed as a GaN layer having a thickness of 7 nm. The quantum well was grown under a growth condition with a temperature of 780° C. and a growth rate of 0.025 nm/sec. On the other hand, the thickness of the GaN layer 104 was set to 50 nm.

With respect to the dimensions of the semiconductor light emitting device, the width of the opening in the mask was set to 5 μm, the width of the stripe was set to 8 μm, and the length of the device in the longitudinal direction of the stripe was set to 1 mm.

The light emitting device thus fabricated was subjected to a test of light emission by optical pumping. FIG. 11 shows the spectrum of light emitted from the device. The emission light was observed from the bottom side of the stripe shaped light emitting device. A threshold value was about 0.8 to 1 MW/cm².

As a result, a peak of induced emission light from the active layer (including 10 quantum wells) was observed at a wavelength of about 405 nm, and a peak of induced emission light from the GaN layer under the mask was observed at a wavelength of about 370 nm. It was confirmed by partial pumping that the peak at a wavelength of about 370 nm is due to induced emission light from the GaN layer under the mask.

### EXAMPLE 2

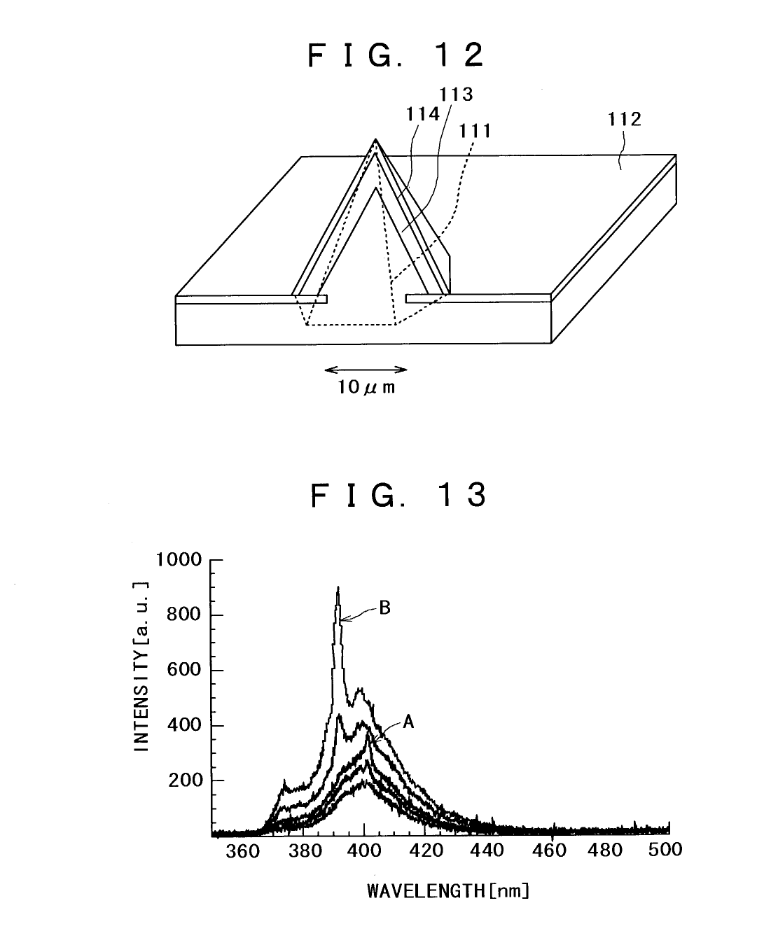

In this example, the present invention is applied to a so-called pyramid shaped semiconductor light emitting device. As shown in FIG. 12, a GaN layer 111 was selectively grown in the form of a polygonal pyramid shape via a mask 112, and an active layer 113 and a GaN layer 114 were selectively grown on the GaN layer 111.

The active layer 113 has a multi-quantum well (MQW) structure including 10 quantum well layers. Each quantum well was formed as an InGaN layer having a thickness of 3 nm, and each barrier was formed as a GaN layer having a thickness of 7 nm. The quantum well was grown under a growth condition with a temperature of 780° C. and a growth rate of 0.025 nm/sec. On the other hand, the thickness of the GaN layer 104 was set to 50 nm. With respect to dimensions of the semiconductor light emitting device, the diameter of an opening in the mask 112 was set to 10 μm.

The light emitting device thus fabricated was subjected to a test of light emission by optical pumping. FIG. 13 shows the spectrum of light emitted from the device. The light emission was observed from the bottom side of the pyramid shaped light emitting device. A threshold value was about 2 MW/cm².

Three pieces of the light emitting devices were pumped, as a result of which a peak A in the figure was first observed and then along with an increase in pumping strength, the peak was shifted to a peak B in the figure.

As is apparent from the above description, according to the present invention, it is possible to realize a semiconductor light emitting device capable of efficiently emitting light by optical pumping. Such a semiconductor light emitting device is applicable as a super luminescent diode or a laser diode in various applications. According to the present invention, it is also possible to realize a semiconductor light emitting device capable of efficiently emitting light not only by optical pumping but also by injection of electrical charges or a combination of optical pumping and injection of electrical charges. According to the present invention, it is further possible to provide a pyramid type semiconductor laser device which has not been proposed until now. According to the present invention, it is still further possible to realize a light emitting apparatus allowing large planar light emission, for example, a planar light emitting laser.

While the preferred embodiments of the present invention have been described using the specific terms, such description is for illustrative purposes only, and it is to be understood that changes and variations may be made without departing from the spirit and scope of the following claims.

What is claimed is:

1. A semiconductor light emitting device comprising:
a tilt crystal made from a compound semiconductor, said tilt crystal having outer planes, at least one of which is taken as a tilt plane; and
an active layer formed on said tilt crystal;
wherein said device generates induced emission light by pumping light absorbed in said active layer.

2. A semiconductor light emitting device according to claim 1, wherein said compound semiconductor is a nitride semiconductor.

3. A semiconductor light emitting device according to claim 2, wherein said active layer has an InGaN layer.

4. A semiconductor light emitting device according to claim 3, wherein the contents of In and Ga in said InGaN layer satisfy a relation of In/(In+Ga)≧0.9.

5. A semiconductor light emitting device according to claim 3, wherein said active layer has a multi-quantum well structure including said InGaN layer as a quantum-well.

6. A semiconductor light emitting device according to claim 1, wherein said tilt crystal has a polygonal pyramid shape.

7. A semiconductor light emitting device according to claim 1, wherein said tilt crystal extends in line in the longitudinal direction, said tilt crystal having a triangular cross-section.

8. A semiconductor light emitting device according to claim 1, wherein said device functions as a super luminescent diode.

9. A semiconductor light emitting device according to claim 1, wherein said device functions as a laser diode.

10. A semiconductor light emitting device according to claim 1, wherein said device is a device comprising:
a crystal layer formed on a substrate, said crystal layer having a tilt crystal plane tilted from the principal plane of said substrate; and
a first conductive type layer, an active layer, and a second conductive type layer, which are formed on said crystal layer in such a manner as to extend within planes parallel to said tilt crystal plane.

11. A semiconductor light emitting device according to claim 10, wherein said crystal layer has a wurtzite type crystal structure.

12. A semiconductor light emitting device according to claim 10, wherein said crystal layer is formed on said substrate via an underlying growth layer by selective growth.

13. A semiconductor light emitting device according to claim 12, wherein said selective growth is performed by selectively removing a portion of said underlying growth layer.

14. A semiconductor light emitting device according to claim 12, wherein said selective growth is performed by making use of an opening selectively formed in a mask layer.

15. A semiconductor light emitting device according to claim 14, wherein said crystal layer is selectively grown in such a manner as to extend outwardly from said opening of said mask layer in the lateral direction.

16. A semiconductor light emitting device according to claim 10, wherein the principal plane of said substrate is the C-plane.

17. A semiconductor light emitting device according to claim 1, wherein said tilt crystal plane includes at least one of the S-plane and the (11-22) plane.

18. A semiconductor light emitting device according to claim 1, wherein a current is injected mainly in said tilt crystal plane.

19. A light emitting apparatus comprising:
an array of a plurality of semiconductor light emitting devices, each of which includes an active layer formed on a tilt plane, said active layer generating induced emission light by oscillation of pumping light;
wherein said apparatus generates planar light emission by optical pumping.

20. A light emitting apparatus according to claim 19, wherein said apparatus functions as a planer light emitting laser.

21. A semiconductor light emitting device comprising:
an active layer including an InGaN layer, said active layer being formed on a tilt crystal;
wherein the contents of In and Ga in said InGaN layer satisfy a relation of In/(In+Ga)≧0.9.

22. A semiconductor light emitting device according to claim 21, wherein said active layer has a multi-quantum well structure including said InGaN layer as a quantum well.

23. A semiconductor light emitting device according to claim 21, wherein said device functions as a super luminescent diode.

24. A semiconductor light emitting device according to claim 21, wherein said device functions as a laser diode.

25. A light emitting apparatus comprising:
an array of a plurality of semiconductor light emitting devices, each of which has an active layer including an InGaN layer, said active layer being formed on a tilt crystal;
wherein the contents of In and Ga in said InGaN layer satisfy a relation of In/(In+Ga)≧=0.9.

26. A light emitting apparatus according to claim 25, wherein said apparatus functions as a planar light emitting laser.

27. A semiconductor laser device, wherein said device has a polygonal pyramid shape.

28. A semiconductor laser device according to claim 27, comprising an InGaN layer as an active layer.

29. A semiconductor laser device according to claim 28, wherein the contents of In and Ga in said InGaN layer satisfy a relation of In/(In+Ga)≧0.9.

30. A semiconductor laser device according to claim 28, wherein said active layer has a multi-quantum well structure including said InGaN layer as a quantum well.

31. A light emitting apparatus comprising:
an array of a plurality of semiconductor laser devices, each of which has a polygonal pyramid shape;
wherein said apparatus generates planar light emission by optical pumping.

32. A light emitting apparatus according to claim 31, wherein said apparatus functions as a planar light emitting laser.
